(19) United States
(12) Patent Application Publication
(10) Pub. No.: US 2006/0136800 A1
(43) Pub. Date: Jun. 22, 2006

(54) Memory system and semiconductor memory device

(75) Inventors: Kuninori Kawabata, Kawasaki (JP); Satoshi Eto, Kawasaki (JP); Yasuhiro Onishi, Kawasaki (JP); Akira Kikutake, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/088,940

(22) Filed: Mar. 25, 2005

(30) Foreign Application Priority Data
Dec. 22, 2004 (JP) 2004-372192

(51) Int. Cl. G11C 29/00

(52) U.S. Cl. 714/763

(57) ABSTRACT

A memory system that can enhance yield without increasing the chip size and without degrading the access time. A single-bit error determination circuit references parity bits required to configure a code capable of correcting a single-bit error, and determines a single-bit error to be corrected; and a double-bit error detection circuit references one redundant bit added to the parity bits, detects a double-bit error, and enables or disables the double-bit error detection in accordance with a selection signal.

### CROSS-REFERENCE TO RELATED APPLICATIONS

This application is based upon and claims the benefits of priority from the prior Japanese Patent Application No. 2004-372192, filed on Dec. 22, 2004, the entire contents of which are incorporated herein by reference.

### BACKGROUND OF THE INVENTION

1. Field of the Invention

The present invention relates to memory systems and semiconductor memory devices, and particularly to a memory system having an error correction function and a semiconductor memory device having an error correction function.

2. Description of the Related Art

The memory capacity demanded of dynamic random access memory (DRAM) and other semiconductor memory devices incorporated in information equipment has been rapidly increasing in recent years. The microfabrication technology has been improved to increase the memory capacity. The improved microfabrication technology, however, degrades the reliability of memory cells.

One conventional technology provides a redundant memory area in a memory cell array and replaces any defective memory cell in the normal memory cell array area with a normal memory cell in the redundant area. This technology must reserve one column of cells in the redundant area for one error bit to be replaced. Recent downsized semiconductor devices, however, contain a greater number of defective memory cells. Therefore, the number of the columns of cells in the redundant area, hereafter referred to as a redundancy count, must be increased to replace all those defective cells. With a greater redundancy count, more error bits can be replaced in an initial function test conducted to obtain redundancy information, and yield is enhanced. This, however, increases the chip size and reduces the number of normal chips that can be obtained from a single wafer. Accordingly, a technology for enhancing yield without increasing the redundancy count is needed.

Recently, more and more memory systems incorporate an error checking and correcting (ECC) function for the sake of improving the performance and yield. One representative memory system includes an ECC circuit for detecting and correcting an error by means of a Hamming code capable of correcting one bit.

FIG. 4 shows an overview of a memory system including an ECC circuit for detecting and correcting an error by utilizing a Hamming code.

A memory core 50 of the memory system includes a data-bit memory area 51 containing 64 data bits, a parity-bit memory area 52 containing 8 parity bits, and a read circuit 53 for reading the data bits and parity bits.

An ECC circuit 60 has a function to detect and correct a single-bit error with reference to the data bits and the parity bits. The ECC circuit 60 includes a single-bit error determination circuit 61, a syndrome decoder 62, an error correction circuit 63, and a data selection circuit 64.

The single-bit error determination circuit 61 references one code made up of as many bits as the sum of the data bits and the parity bits, and determines whether the single code contains a single-bit error.

To configure a Hamming code capable of correcting one bit, 4 parity bits would be usually required for 8 data bits; 5 parity bits would be required for 16 data bits; 6 parity bits would be required for 32 data bits; and 7 parity bits would be required for 64 data bits. An example of 64 data bits and 7 parity bits will be described below.

The single-bit error determination circuit 61 creates a 7-bit syndrome signal based on the Hamming code, as a result of single-bit error determination, and sends the signal to the syndrome decoder 62. If the read data bits and parity bits are correct, all the bits of the syndrome signal are set to zero. If there is an error, the syndrome signal represents an error pattern, which identifies the error bit.

The syndrome decoder 62 decodes the 7-bit syndrome signal, and generates a 64-bit error-bit identification flag signal, which identifies the location of the error.

The error correction circuit 63 inverts the data at the address located by the error-bit identification flag signal, and corrects the single-bit error.

The data selection circuit 64 outputs the corrected 64-bit data from input-output pins, which are not shown in the figure, in groups of 16bits.

FIG. 5A and FIG. 5B are diagrammatic sketches showing the conventional error correction based on a Hamming code. Shown in FIG. 5A is the error correction performed when one code contains one error bit. Shown in FIG. 5B is the error correction performed when one code contains two error bits.

In FIG. 5A and FIG. 5B, a circle represents a normal bit, and a cross represents an error bit. The figures also show that the error correction circuit 63 shown in FIG. 4 includes a plurality of exclusive OR (XOR) circuits 63a. In accordance with the error-bit identification flag signal generated by the syndrome decoder 62 shown in FIG. 4, the XOR circuit 63a inverts and outputs a bit for which an error-bit identification flag is set. In FIG. 5A, the single error bit is properly corrected and output. If one code contains two error bits although the Hamming code is not capable of correcting two bits, a correct bit in the code would be inverted to provide three error bits, as shown in FIG. 5B. This operation would turn out to increase the number of error bits.

A memory system developed to prevent that kind of undesired operation includes an ECC circuit for correcting and detecting an error by means of an extended Hamming code capable of correcting a single-bit error and detecting a double-bit error, as disclosed in Japanese Unexamined Patent Publication No. H11-102326 (paragraph numbers 0018 and 0019) and Japanese Unexamined Patent Publication No. 2000-149598 (paragraph number 0015), for instance. An extended Hamming code is obtained by adding one parity bit for detecting a double-bit error to a Hamming code.

FIG. 6 shows an overview of a memory system including an ECC circuit for detecting and correcting an error by means of an extended Hamming code.

An ECC circuit 70 for detecting and correcting an error by means of an extended Hamming code has a function to correct a single-bit error and to detect a double-bit error. The ECC circuit 70 includes a single-bit error determination and double-bit error detection circuit 71, a syndrome decoder 72, an error correction circuit 73, and a data selection circuit 74.

The single-bit error determination and double-bit error detection circuit 71 references 64 data bits and 8 parity bits, for instance, and determines whether one code contains a single-bit error to be corrected and whether the code contains a double-bit error. To be more specific, the single-bit error determination and double-bit error detection circuit 71 creates an 8-bit syndrome signal based on the extended Hamming code, and sends the signal to the syndrome decoder 72.

The syndrome decoder 72 decodes the 8-bit syndrome signal, and generates a 64-bit error-bit identification flag signal, which identifies the location of the single-bit error to be corrected.

The error correction circuit 73 inverts the data at the address located by the error-bit identification flag signal, and corrects a single-bit error. If a double-bit error is detected, the error correction circuit 73 does not invert the data.

The data selection circuit 74 outputs the corrected 64-bit data from input-output pins, which are not shown in the figure, in groups of, for example, 16 bits.

FIG. 7A and FIG. 7B are diagrammatic sketches showing the conventional error correction based on the extended Hamming code. Shown in FIG. 7A is the error correction performed when one code contains one error bit. Shown in FIG. 7B is the error correction performed when one code contains two error bits.

In FIG. 7A and FIG. 7B, a circle represents a normal bit, and a cross represents an error bit. The figures also show that the error correction circuit 73 shown in FIG. 6 includes a plurality of XOR circuits 73a. In accordance with the error-bit identification flag signal generated by the syndrome decoder 72 shown in FIG. 6, the XOR circuit 73a inverts a bit for which an error-bit identification flag is set.

In FIG. 7A, one error bit is properly corrected and output, as with the Hamming code described earlier. If there are two error bits, the data is output without setting an error-bit identification flag and without inverting any bit, as shown in FIG. 7B. Unlike the operation with a Hamming code, this operation will not increase the error bits.

If the single-bit error correction and double-bit error detection function, as provided by an Extended Hamming code, is used, an operation utilizing the additional parity bit is performed, and the access time is made longer. Accordingly, an error correction function capable of correcting one bit, as provided by a Hamming code, is usually preferred.

In an initial function test conducted to obtain a redundancy count and other redundancy information required to replace an error bit, the error correction function is disabled because the function may increase errors if there are two or more error bits, as described earlier. When the initial function test shows that the total number of error bits exceeds a certain redundancy count, a chip having just a single-bit error in one code is disposed as a defective chip. Because a chip that can be actually saved by the error correction function is disposed, yield cannot be enhanced.

If the redundancy count is increased to enhance yield, the chip size increases, increasing the cost of a mass-produced chip.

### SUMMARY OF THE INVENTION

In view of the foregoing, it is an object of the present invention to provide a memory system and a semiconductor memory device which can enhance yield without increasing the chip size and without degrading the access time.

To accomplish the above object, according to the present invention, there is provided a memory system having a function to detect and correct an error bit. This memory system includes the following elements: a determination circuit which references data bits stored in the memory core and parity bits required to configure a code capable of correcting a single-bit error, and determines a single-bit error to be corrected; and a detection circuit which has a function to detect a double-bit error by referencing the data bits and one redundant bit added to the parity bits, and enables or disables the double-bit error detection in accordance with a selection signal.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 shows the configuration of a memory system of an embodiment of the present invention.

FIG. 2 shows the configuration of a general DRAM core.

FIG. 3 is a detailed view of a single segment of the DRAM core shown in FIG. 2.

FIG. 4 shows an overview of a memory system including an ECC circuit for detecting and correcting an error by utilizing a Hamming code.

FIG. 5A is a diagrammatic sketch showing the conventional error correction based on a Hamming code. This type of error correction is performed when one code contains one error bit.

FIG. 5B is a diagrammatic sketch showing the conventional error correction based on a Hamming code. This type of error correction is performed when one code contains two error bits.

FIG. 6 shows an overview of a memory system including an ECC circuit for detecting and correcting an error by means of an extended Hamming code.

FIG. 7A is a diagrammatic sketch showing the conventional error correction based on an extended Hamming code. This type of error correction is performed when one code contains one error bit.

FIG. 7B is a diagrammatic sketch showing the conventional error correction based on an extended Hamming code. This type of error correction is performed when one code contains two error bits.

### DESCRIPTION OF THE PREFERRED EMBODIMENTS

Embodiments of the present invention will be described in detail with reference to the drawings.

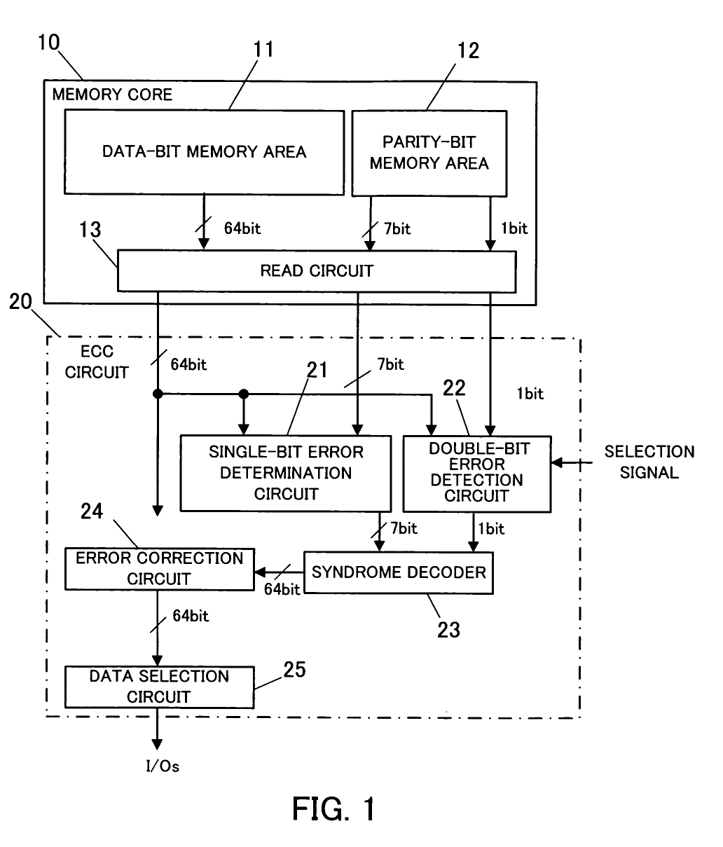

FIG. 1 shows the configuration of a memory system of an embodiment of the present invention. The memory system includes a memory core 10 and an ECC circuit 20.

The memory core 10 includes a data-bit memory area 11 containing 64 data bits and a parity-bit memory area 12 containing 8 parity bits, for instance.

A parity bit is generated in accordance with the principle of a code capable of correcting a single-bit error or a code capable of correcting a single-bit error and detecting a double-bit error. The code capable of correcting a single-bit error and the code capable of correcting a single-bit error and detecting a double-bit error will be described respectively as a Hamming code and an extended Hamming code, but are not limited to those codes.

Usually, a Hamming code has 4 parity bits for 8 data bits, 5 parity bits for 16 data bits, 6 parity bits for 32 data bits, or 7 parity bits for 64 data bits. As the code length increases, the ratio of parity bits to data bits decreases, and the chip size can be reduced. In terms of the chip size, a Hamming code having 6 parity bits for 32 data bits or 7 parity bits for 64 data bits is generally used. A 64:7-bit Hamming code will be taken as an example in the following description. An extended Hamming code requires one more parity bit than a Hamming code.

A read circuit 13 reads the data bits and the parity bits from the memory core 10. The configuration of the memory core 10 will be described later.

The ECC circuit 20 includes a single-bit error determination circuit 21, a double-bit error detection circuit 22, a syndrome decoder 23, an error correction circuit 24, and a data selection circuit 25.

The single-bit error determination circuit 21 references 64 data bits in the memory core 10 and 7 parity bits required to configure a Hamming code capable of correcting a single-bit error, and determines whether one code has a single-bit error to be corrected. The single-bit error determination circuit 21 includes a matrix of XOR circuits, for instance. The single-bit error determination circuit 21 creates a 7-bit syndrome signal based on the Hamming code, and sends the signal to the syndrome decoder 23. If the read data bits and parity bits are correct, all the bits of the syndrome signal are set to zero. If there is an error, the signal represents an error pattern, which identifies the error bit.

The double-bit error detection circuit 22 references 64 data bits and one redundant bit added to the 7 parity bits, and detects a double-bit error. The double-bit error detection circuit 22 includes a matrix of XOR circuits, for instance. The double-bit error detection circuit 22 generates a one-bit syndrome signal indicating whether there is a double-bit error, and sends the signal to the syndrome decoder 23. The double-bit error detection circuit 22 also enables or disables the double-bit error detection, in accordance with a selection signal input from the outside. The selection signal is, for instance, a test signal input via an external input-output terminal, which is not shown in the figure, when an initial function test is conducted to obtain a redundancy count and other redundancy information required to correct an error bit. The double-bit error detection circuit 22 enables the double-bit error detection just in the function test, and disables the double-bit error detection otherwise.

The syndrome decoder 23 decodes the 7-bit syndrome signal, generates a 64-bit error-bit identification flag signal, and sends the signal to the error correction circuit 24. If the syndrome decoder 23 receives a signal indicating that a double-bit error is detected while the double-bit error detection circuit 22 enables the double-bit error detection, the syndrome decoder 23 references a total of 8 bits, generates a signal indicating that the error bit is not identified in accordance with the extended Hamming code, and sends the signal to the error correction circuit 24.

The error correction circuit 24 inverts data at the address located by the error-bit identification flag signal, and corrects the single-bit error. If a double-bit error is detected, no data is inverted.

The data selection circuit 25 outputs the corrected 64-bit data from input-output pins, which are not shown in the figure, in groups of, for example, 16 bits.

The memory system as shown in FIG. 1 is implemented, for instance, as a semiconductor memory device such as a DRAM with a built-in ECC function.

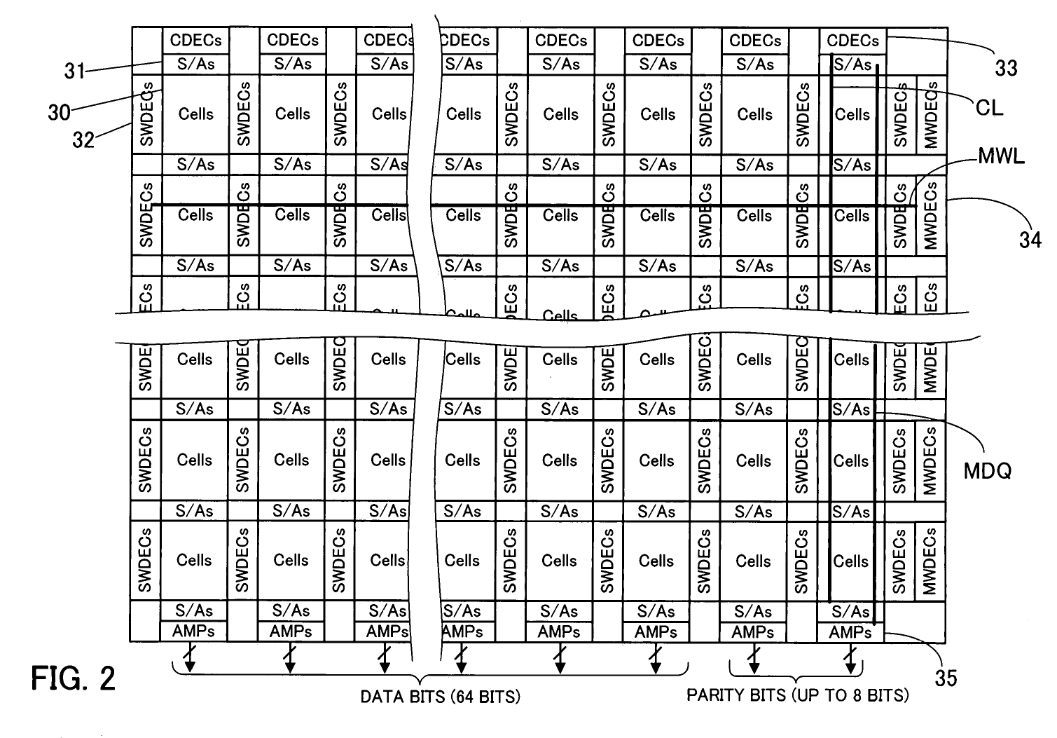

The memory core 10 will next be described in further detail. FIG. 2 shows the configuration of a general DRAM core. The DRAM core has a plurality of segments, each including a memory cell array 30, a group of sense amplifiers 31, and a group of sub-word decoders 32. A group of column decoders 33 for selecting a column selection line CL is provided in each column of segments. A group of main word decoders 34 for selecting a main word line MWL is provided in each row of segments. A group of amplifiers 35 corresponds to the read circuit 13 shown in FIG. 1, and outputs data read by the group of sense amplifiers 31 through main data bus lines MDQ.

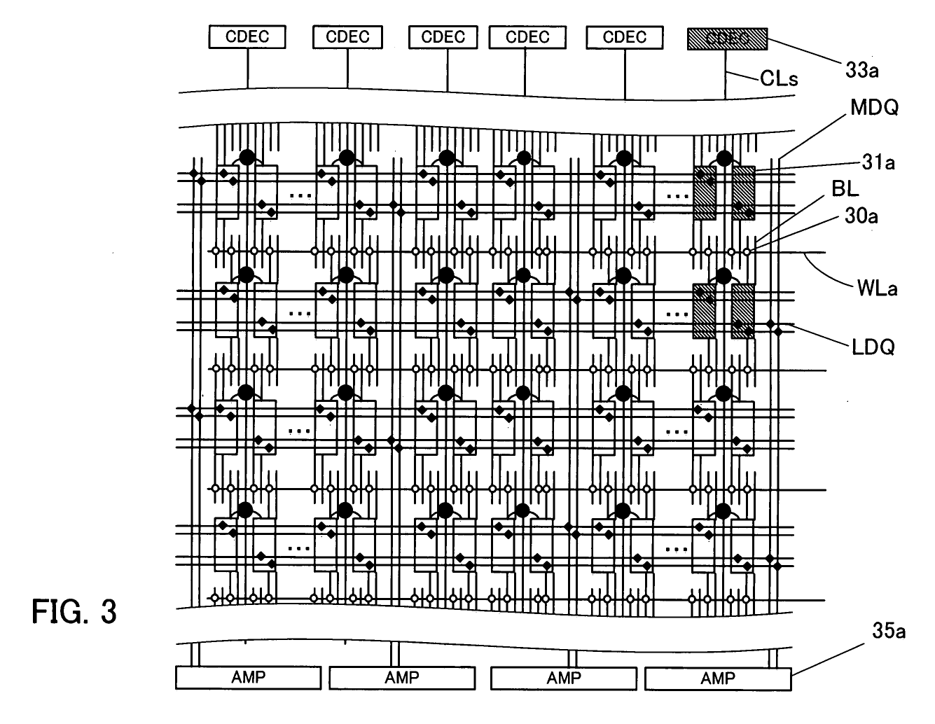

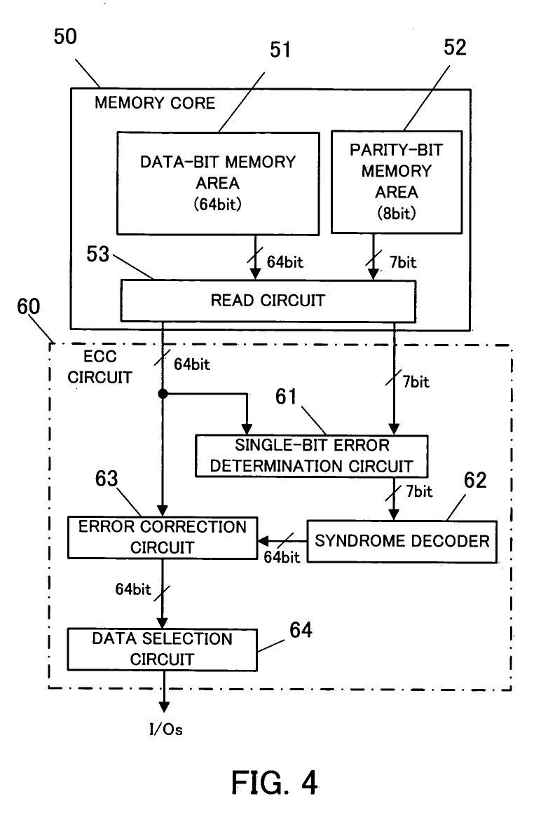

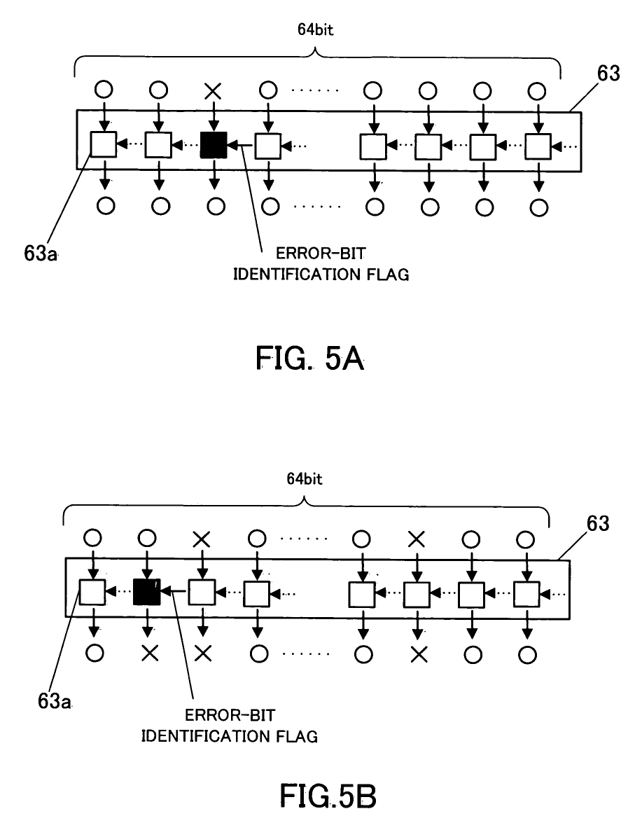

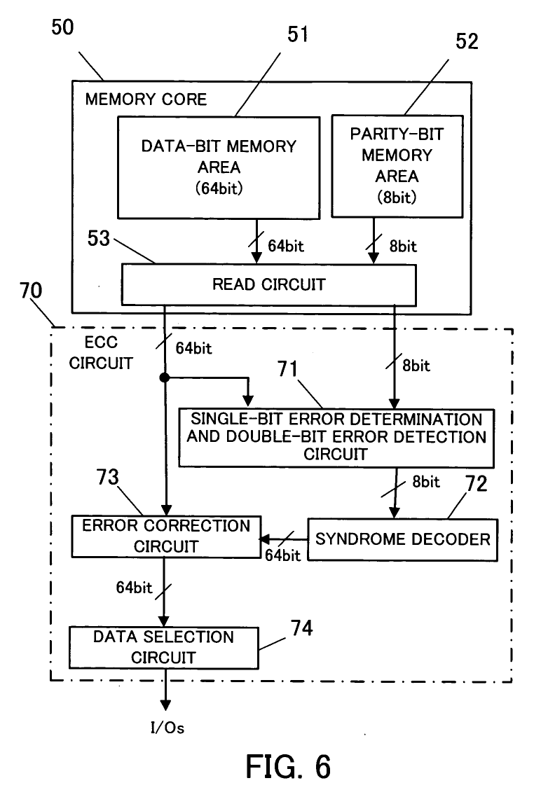

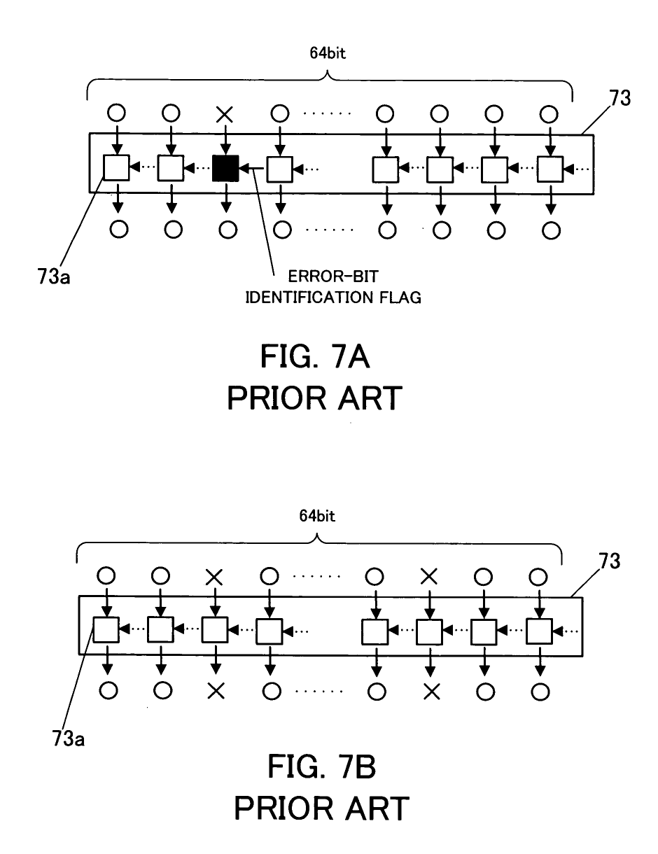

FIG. 3 is a detailed view of a single segment of the DRAM core shown in FIG. 2. In the DRAM core including a matrix of memory cells 30a, as shown in the figure, selecting one column selection line CL selects a plurality of sense amplifiers (four sense amplifiers in many cases) When a column decoder 33a selects a column selection line CLs, and when a sub-word decoder, not shown in the figure, activates a word line WLa, four sense amplifiers 31a are selected, as shown in FIG. 3. The data of the relative memory cells 30a is read through pairs of bit lines BL connected to the sense amplifiers 31a. The read data is sent through four pairs of horizontal local data bus lines LDQ to four pairs of vertical main data bus lines MDQ, which are connected to different amplifiers 35a. Data stored in the DRAM core are read in that way.

If a 64:7-bit Hamming code is applied to the memory core 10 as described above, the memory area assigned to the parity bits includes one redundant cell, which is not used usually. The memory system of the embodiment of the present invention uses this redundant cell as an extra bit for configuring an extended Hamming code.

The operations of the memory system of the embodiment of the present invention will be described with reference to FIG. 1. First, the operation of the memory system in an initial function test for obtaining redundancy information will be described.

If the function test finds a single-bit error in one code, the single-bit error determination circuit 21 references the 64 data bits and 7 parity bits in the memory core 10, creates a 7-bit syndrome signal, and sends the signal to the syndrome decoder 23. The syndrome decoder 23 decodes the 7-bit syndrome signal, generates a 64-bit error-bit identification flag signal, which identifies the location of the error, and sends the signal to the error correction circuit 24. The error correction circuit 24 inverts the data at the address located by the error-bit identification flag signal, and corrects the single-bit error. The corrected data is output through the data selection circuit 25.

If the function test finds a double-bit error in one code, the double-bit error detection circuit 22 references the 64 data bits and the single redundant bit read from the memory core 10, and detects the double-bit error in accordance with the extended Hamming code. The double-bit error detection circuit 22 sends a one-bit signal indicating that a double-bit error has been detected, to the syndrome decoder 23. At the reception of the one-bit signal, the syndrome decoder 23 sends, for example, a signal for not setting an error-bit identification flag, to the error correction circuit 24 to prevent error correction in the error correction circuit 24. The error correction circuit 24 outputs the data through the data selection circuit 25 without correcting the double-bit error. When this occurs, the error will be corrected by means of the redundant area of the memory cell array.

When a double-bit error is detected, the single-bit error determination circuit 21 may receive a signal indicating that a double-bit error has been detected, from the double-bit error detection circuit 22, and may generate a signal for not identifying the error bit and send the signal to the syndrome decoder 23, so that the error bit will not be flagged.

If a function test finds a single-bit error in one code, the error is not corrected by means of the redundant area, but is corrected by the error correction function. A redundant cell is used only when two or more error bits are found. Accordingly, yield can be enhanced without increasing the redundancy count, which prevents the chip size to be increased.

In the normal operation after the initial function test, in an access test, or in another mode, the double-bit error detection by the double-bit error detection circuit 22 is disabled by a selection signal. This disables the one-bit syndrome signal output from the double-bit error detection circuit 22, and the syndrome decoder 23 generates an error-bit identification flag signal from the 7 parity bits. If a single-bit error occurs, the error correction circuit 24 corrects the error, and the data selection circuit 25 outputs the corrected data.

Use of the redundant bit increases the number of logic processing stages to be performed by the double-bit error detection circuit 22 and the syndrome decoder 23 in the normal operation or in the access test, and slows down the operation speed. However, the double-bit error detection is enabled only in the function test, and the access time will not be made longer.

In the memory core 10 configured as shown in FIG. 3, the cells selected by selecting a column selection line CL are more than the bits required to correct a single-bit error in a code. Accordingly, a system capable of detecting a single-bit error can be switched to a system capable of correcting a single-bit error and detecting a double-bit error, just by assigning an extra bit as a redundant bit required to configure a code capable of detecting a double-bit error, without increasing the chip size.

According to the present invention, a single-bit error to be corrected is determined with reference to parity bits required to configure a code capable of correcting a single-bit error, a double-bit error is detected with reference to a redundant bit added to the parity bits, and the double-bit error detection is enabled or disabled in accordance with a selection signal given from the outside. Whether to perform just the single-bit error correction or to perform both the single-bit error correction and the double-bit error detection can be selected by the selection signal. For instance, by performing the single-bit error correction and the double-bit error detection in an initial function test conducted to obtain redundancy information, yield can be enhanced without increasing the redundant count. In the normal operation, degrading the access time can be prevented by disabling the double-bit error detection.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A memory system having a function to detect and correct an error bit, the memory system comprising:
a determination circuit for referencing data bits stored in a memory core and parity bits required to configure a code capable of correcting a single-bit error, and for determining a single-bit error to be corrected; and
a detection circuit having a function to detect a double-bit error by referencing the data bits and one redundant bit added to the parity bits, for enabling and disabling the double-bit error detection in accordance with a selection signal.

2. The memory system according to claim 1, further comprising:
a syndrome decoder for decoding a first syndrome signal output from the determination circuit and for generating a signal for identifying the error bit, and for unidentifying the error bit in accordance with a second one-bit syndrome signal output from the detection circuit if a double-bit error is detected.

3. The memory system according to claim 1, wherein the selection signal is a test signal input in a function test; and
the detection circuit enables the double-bit error detection just in the function test and disables the double-bit error detection otherwise.

4. The memory system according to claim 1, wherein the determination circuit determines a single-bit error by means of a Hamming code or an extended Hamming code.

5. The memory system according to claim 1, wherein the detection circuit detects a double-bit error by means of an extended Hamming code.

6. The memory system according to claim 1, wherein the memory core is structured to allow a plurality of cells to be selected by selecting a single column selection line; and if the bits selected by selecting a column selection line for selecting parity bits required to configure a code capable of correcting a single-bit error outnumber the parity bits, an extra bit can be used as the redundant bit.

7. The memory system according to claim 1, wherein the parity bits are stored in the memory core.

8. The memory system according to claim 1, wherein the selection signal is input from the outside.

9. The memory system according to claim 1, wherein the determination circuit generates a signal for unidentifying the error bit if the detection circuit detects a double-bit error.

10. A semiconductor memory device having a function to detect and correct an error bit, the semiconductor memory device comprising:
a determination circuit for referencing data bits stored in a memory core and parity bits required to configure a code capable of correcting a single-bit error, and for determining a single-bit error to be corrected; and
a detection circuit having a function to detect a double-bit error by referencing the data bits and one redundant bit added to the parity bits, for enabling and disabling the double-bit error detection in accordance with a selection signal.
